(19) United States
(12) Patent Application Publication
(10) Pub. No.: US 2025/0210417 A1
(43) Pub. Date: Jun. 26, 2025

(54) THERMAL SENSOR FUSION

(71) Applicant: Advanced Micro Devices, Inc., Santa Clara, CA (US)

(72) Inventors: Gabriel H. Loh, Bellevue, WA (US); Thomas D. Burd, Santa Clara, CA (US)

(73) Assignee: Advanced Micro Devices, Inc., Santa Clara, CA (US)

(21) Appl. No.: 18/393,828

(22) Filed: Dec. 22, 2023

(51) Int. Cl. H01L 21/66; H01L 27/06

(52) U.S. Cl. CPC H01L 22/12; H10D 84/204

(57) ABSTRACT

A method includes forming a plurality of thermal sensing elements at predetermined locations on a semiconductor chip proximate to a target location, measuring a temperature of the semiconductor chip at each predetermined location using a corresponding one of the plurality of thermal sensing elements, and determining a temperature at the target location using the temperatures measured at each of the predetermined locations.

### BACKGROUND

Approaches to thermal management are ubiquitous within the microprocessor industry where rapid performance growth has been accompanied by an increase in transistor density and an attendant increase in heat generation within electronic packages. Absent effective solutions, excessive heat retention and large thermal gradients can adversely impact the performance and reliability of semiconductor devices.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 illustrates aspects of an example model for predicting the temperature of a hotspot within a semiconductor chip according to various implementations.

FIG. 2 is a thermal map of a semiconductor chip illustrating the principle of operation of the disclosed model according to some implementations.

FIG. 3 is a thermal map of a semiconductor chip illustrating the predictive efficiency of the disclosed model according to some implementations.

FIG. 4 is a thermal map of a semiconductor chip illustrating the predictive efficiency of the disclosed model according to further implementations.

FIG. 5 is a schematic diagram of a semiconductor chip illustrating thermal sensor placement in accordance with certain implementations.

FIG. 6 is a schematic diagram of a stacked semiconductor chip illustrating thermal sensor placement in accordance with certain implementations.

FIG. 7 is a flowchart describing an example method of evaluating a temperature of a semiconductor chip according to certain implementations.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

Disclosed are a methodology and system for determining chip temperatures during operation. More specifically, a real-time model can be used to evaluate the temperatures of sensor-inaccessible target areas on a chip using thermal data from adjacent accessible locations. Target area temperatures can be used to control the operation of an associated device.

Thermal sensors, such as thermal diodes or thermal ring oscillators, can be formed directly on a semiconductor chip and used to measure the chip's temperature profile during use. Sensor output can be integrated into a feedback loop that is configured to modify the chip's operation, including its power consumption while running various processes. Efficient thermal monitoring can be used to maintain power consumption and chip temperatures within their specifications.

In some systems, it can be challenging to obtain accurate thermal readings because the thermal sensors cannot be placed directly in the hottest regions of the chip due to competing real estate interests such as with performance-critical logic. Moreover, the placement of larger sensors in certain locations can adversely interfere with the chip's local thermal equilibrium environment. As a result, thermal sensors are located outside of critical and dense areas of a chip, which can be beneficial for floor-planning, but can lead to significant errors in reported temperatures.

As integration density increases, accurate and effective thermal management will be increasingly important. Notwithstanding recent developments, it would be advantageous to have accurate and relevant thermal data that can be used to guide efficient and reliable chip function, including reduced margining and improved dynamic voltage and frequency scaling (DVFS).

Disclosed are a method and system that utilize multiple thermal sensors to predict temperature information within critical regions of a semiconductor chip. In a ‘sensor fusion’ paradigm, data from individual thermal sensors as well as temperature gradient data measured between adjacent sensors are combined to provide accurate and precise chip temperature information.

By locating the thermal sensors outside of critical areas, their placement can be less restrictive (less impact on critical areas) while simultaneously delivering higher accuracy temperature readings. This can lead to the use of fewer thermal sensors overall and higher performance by decreasing margins related to overheating. This approach can be implemented in existing processors through firmware upgrades.

The disclosed methodology can be used with various processor types, including CPUs, GPUs, FPGAS, ACAPs, neural accelerators, analog devices, memories, etc., and in both low-power embedded chips and high-power server and HPC chips. Moreover, the approach is compatible with silicon-based processors as well as with processors/circuits manufactured with other semiconductors, including GaAs, GaN, and the like.

According to particular instantiations, readings from multiple thermal sensors (TSENs) can be used to generate an accurate prediction of the actual temperature of a hotspot. Generally, if a chip (or core) has N thermal sensors (TSEN1, TSEN2, . . . , TSENN), then a function TSEN_{pred}=f(TSEN1, TSEN2, . . . , TSENN) can be used to predict a chip hotspot temperature.

In one example, individual thermal sensor readings can be combined with the differences/gradients between pairs of thermal sensors weighted by calibrated constants to generate a more accurate hotspot prediction than could be obtained from any single thermal sensor.

The use of multiple differences/gradients allows the prediction function to distinguish between a wider range of thermal scenarios, including a variety of hotspots, and to continue performing accurately in less extreme (cooler) thermal situations.

While the prediction function can be evaluated with respect to each of the chip's (or core's) thermal sensor (TSEN) readings, further implementations can utilize functions that incorporate a subset of the thermal sensor readings. Still further implementations can incorporate information other than thermal sensor (TSEN) readings, such as performance counters, activity counters/monitors (e.g., dynamic CaC readings), a dynamic processor state (e.g., current, voltage and/or frequency settings), configuration information (e.g., from machine-specific registers, BIOS settings, software-specified values), etc. The thermal sensor readings can be obtained from a single chip, or one or more of the thermal sensor readings can be obtained from a different chip than where the hotspot is located, such as in 3D-stacked multi-chip architectures or a 2.5D integrated system, and the like.

A processor or chip configuration can warrant multiple predictive functions and some functions can use a different subset of thermal sensor readings and/or other information along with different sets of calibrated function constants to provide more accurate hotspot predictions for multiple different chip locations/tiles/common hotspots. For example, one function can use a first subset of thermal sensor readings and activity counters associated with the integer scheduler unit to predict the hotspot of the integer scheduler block, while a second function can use a different set of thermal sensor readings and activity counters associated with the floating point/SIMD pipeline to predict the hotspot temperature of the floating point pipeline.

Disclosed are methods for thermally monitoring and controlling the operation of an integrated circuit. An exemplary method includes forming a plurality of thermal sensing elements at predetermined locations on a semiconductor chip proximate to a target location, measuring a temperature of the semiconductor chip at each predetermined location using a corresponding one of the plurality of thermal sensing elements, and determining a temperature at the target location using the temperatures measured at each of the predetermined locations.

In particular implementations, the thermal sensing elements can include thermal diodes or thermal ring oscillators that are integrated into the chip. The target location can correspond to a known or suspected hotspot, such as the location of a CPU core. Temperature readings from one or more of the individual sensing elements can be combined with temperature gradients between pairs of sensing elements to generate a temperature prediction for the target location. In certain models, the various temperature gradients can be weighted by calibration constants to provide an accurate hotspot prediction.

According to a further example, the temperature at the target location can be determined from a temperature measured at a plurality of the predetermined locations, and operational information for the semiconductor chip selected from a performance counter, an activity counter, a dynamic processor state, and configuration information.

The model can use one or more of the maximum temperature measured at the predetermined locations and the temperature at the predetermined location located nearest to the target location. In some instantiations, a distance between the target location and each predetermined location can be less than approximately 500 micrometers.

A still further method can include forming a plurality of thermal sensing elements on a semiconductor chip, measuring a temperature of the semiconductor chip corresponding to each respective thermal sensing element, and determining a temperature at a target location on the semiconductor chip using two or more temperature measurements from the plurality of thermal sensing element.

An associated system includes a semiconductor chip having a target location, and a plurality of thermal sensing elements located on the semiconductor chip proximate to the target location, where the target location includes a hotspot. The system is configured to utilize multiple thermal sensor readings, and based on a function of the readings, cause operation of the semiconductor chip to be adjusted in a thermally beneficial way, such as by decreasing power to continue operation within an established thermal budget, or increasing power to convert available thermal headroom into improved higher performance. Further example operational adjustments can include one or more of decreasing voltage, decreasing clock frequency, and decreasing a number of instructions executed per cycle. The system can include appropriate interfaces to report the predicted temperature to software layers, including OS, hypervisor, and performance/system monitoring tools.

Features from any of the implementations described herein can be used in combination with one another in accordance with the general principles described herein. These and other implementations, features, and advantages will be more fully understood upon reading the following detailed description in conjunction with the accompanying drawings and claims.

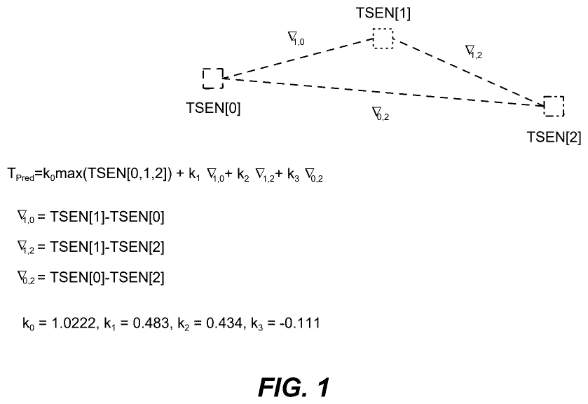

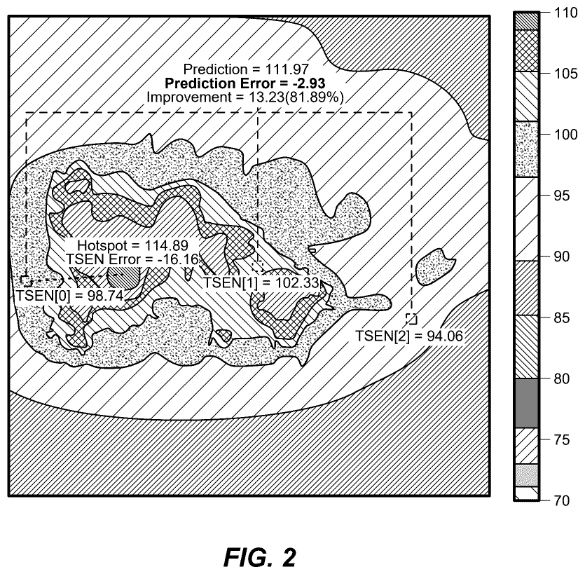

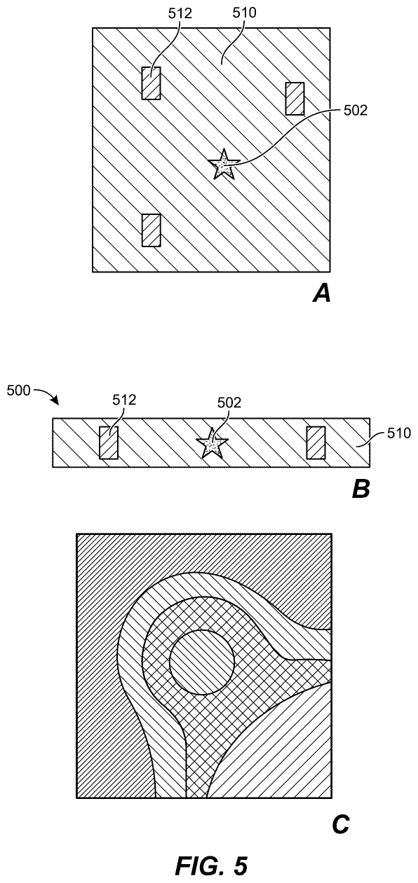

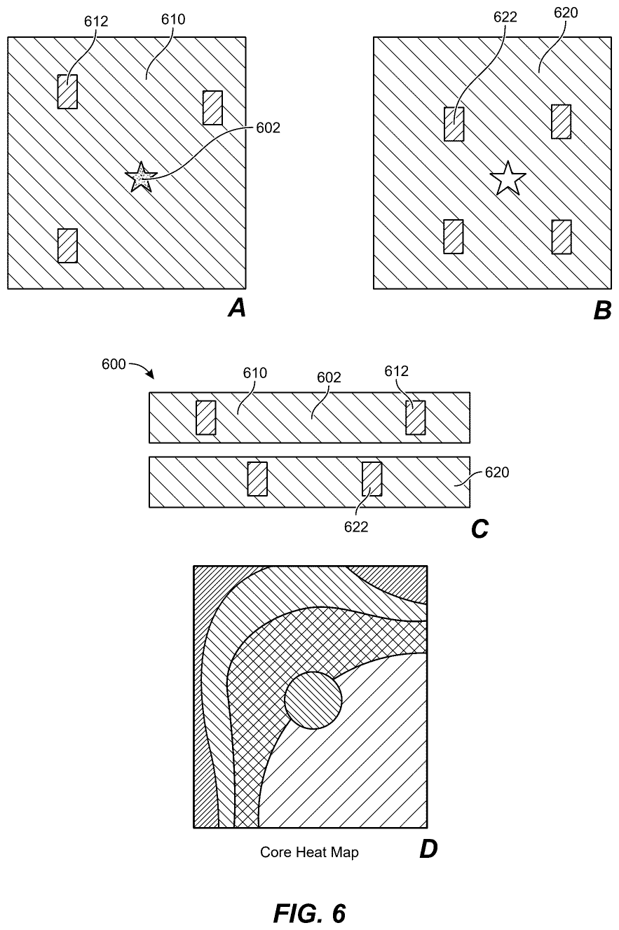

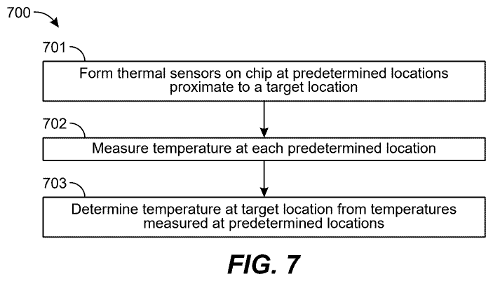

The present disclosure is generally directed to the thermal management of a semiconductor device or chip, and more particularly to a predictive model for indirectly assessing the temperature of a known hotspot and accordingly adjusting operation of the device or chip. Aspects of the model according to particular implementations are illustrated in FIG. 1. Thermal scans showing the local environment of a hotspot and the beneficial impact of the model on assessing the hotspot temperature are shown in FIGS. 2-4. Example chip architectures showing co-integrated thermal sensors are shown schematically in FIGS. 5 and 6. A flow chart depicting a method for evaluating the temperature of a semiconductor chip is shown in FIG. 7.

Turning to FIG. 1, a predictive model utilizes a plurality of thermal sensors (TSEN0, TSEN1, TSEN2, etc.) that are integrated into available locations on a semiconductor chip. Although a methodology using three thermal sensors is illustrated, it will be appreciated that a greater number of thermal sensors can be used.

Shown also is a predictive function for determining the temperature (T_{Pred}) of a hotspot located on the semiconductor chip. The function evaluates the hotspot temperature as the weighted sum of the maximum thermal sensor value and the inter-sensor temperature gradients. The calibrated function constants k₀-k₃ can be determined empirically for a given chip architecture and use case, for example.

FIG. 2 is an illustrative thermal scan showing the temperature profile for a semiconductor chip. The temperature profile can be determined using an optical temperature sensor, for example. Individual thermal sensor measurements are shown together with the hotspot temperature. Relative to the thermal sensor (TSEN[0]) located nearest to the hotspot, the thermal sensor error of approximately 16 degrees is significant.

Shown also is the modeled hotspot temperature that was determined using the predictive function and function constants illustrated in FIG. 1. As will be appreciated, the predicted hotspot temperature of approximately 112 degrees represents a nearly 82% improvement relative to a thermal sensor value taken alone.

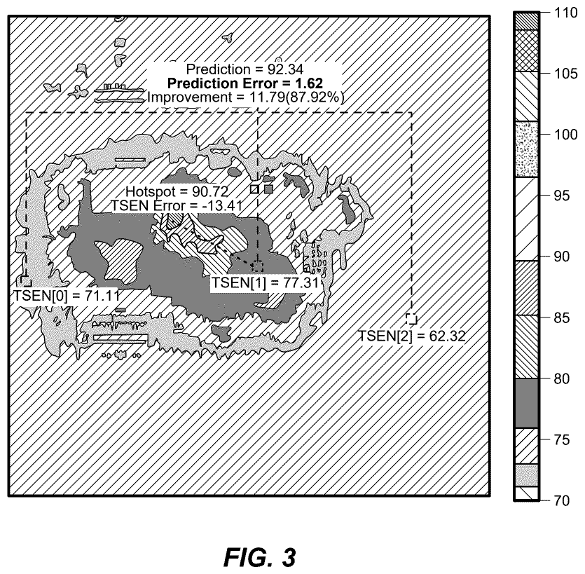

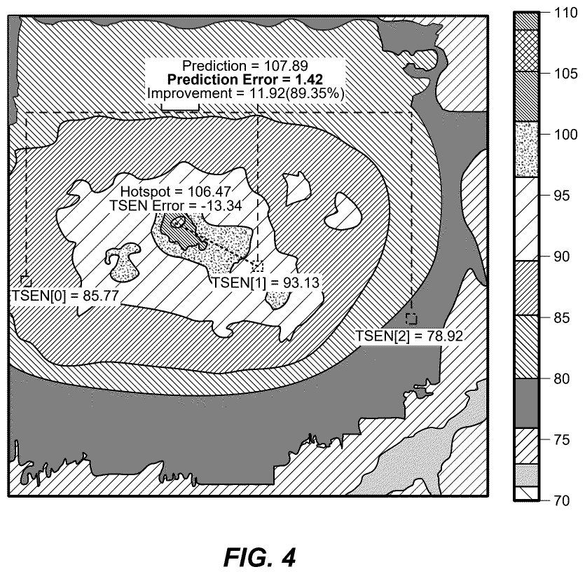

Referring to FIG. 3 and FIG. 4, shown are two further predictive examples that include a relatively cool chip and a chip operating at moderate temperatures, respectively, where in each case the disclosed method provides a significantly more accurate prediction of each chip's hotspot temperature relative to any individual thermal sensor measurement.

Thermal sensors can be located on a semiconductor chip proximate to known hotspots and can be configured to provide direct, interpolative, or extrapolative measurements. Referring to FIG. 5, shown schematically is a semiconductor chip 500 including a die 510. In both the top down plan view (FIG. 5A) and the cross-sectional view (FIG. 5B), a hotspot 502 is identified and the placement of a plurality of thermal sensors 512 adjacent to the hotspot 502 is shown. FIG. 5C is a thermal map showing the distribution of heat across die 510.

Turning to FIG. 6, shown is a semiconductor chip 600 having a 3D architecture and including both an upper die 610 and a lower die 620. A known hotspot 602 is located on the upper die. Thermal sensors configured to evaluate the temperature profile of semiconductor chip 600 can be located on both the upper die 610 and the lower die 620. In the illustrated example, and with reference to FIGS. 6A, 6B, and 6C, a first bank of thermal sensors 612 can be located proximate to hotspot 602 on upper die 610, and a second bank of thermal sensors 622 can be located below the hotspot 602 on lower die 620. A 3D sensor architecture can be arranged to provide a denser sensor configuration and hence a more accurate temperature measurement with more sensors located closer to the hotspot than can be achieved using a 2D sensor configuration. FIG. 6D is a thermal map showing the distribution of heat across upper die 610.

Referring to FIG. 7, depicted is an example method for evaluating the temperature of a semiconductor chip. The method 700 can include forming a plurality of thermal sensing elements at predetermined locations on a semiconductor chip proximate to a target location (701), measuring a temperature of the semiconductor chip at each predetermined location using a corresponding one of the plurality of thermal sensing elements (702), and determining a temperature at the target location using the temperatures measured at each of the predetermined locations (703).

In the illustrated examples, the prediction function is based on maximum thermal sensor values and a linear combination of inter-sensor gradients. It will be appreciated, however, that other functional forms and inputs are contemplated. Furthermore, in some instantiations, the prediction function can be trained using machine learning algorithms (e.g., a neural network) in an on-going manner or only initially where the function starts from a machine learning algorithm and is subsequently simplified into an equation that is easier or more economical to evaluate.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

The term “approximately” in reference to a particular numeric value or range of values can, in certain implementations, mean and include the stated value as well as all values within 10% of the stated value. Thus, by way of example, reference to the numeric value “50” as “approximately 50” can, in certain implementations, include values equal to 50±5, i.e., values within the range 45 to 55.

The term “substantially” in reference to a given parameter, property, or condition can mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition can be at least approximately 90% met, at least approximately 95% met, or even at least approximately 99% met.

It will be understood that when an element such as a layer or a region is referred to as being formed on, deposited on, or disposed “on” or “over” another element, it can be located directly on at least a portion of the other element, or one or more intervening elements can also be present. In contrast, when an element is referred to as being “directly on” or “directly over” another element, it can be located on at least a portion of the other element, with no intervening elements present.

While various features, elements or steps of particular implementations can be disclosed using the transitional term “comprising,” it is to be understood that alternative implementations, including those that can be described using the transitional phrases “consisting of” or “consisting essentially of,” are implied. Thus, for example, implied alternative implementations to a semiconductor substrate that comprises or includes silicon include implementations where a semiconductor substrate consists essentially of silicon and implementations where a semiconductor substrate consists of silicon.

What is claimed is:

1. A method comprising:
forming a plurality of thermal sensing elements at predetermined locations on a semiconductor chip proximate to a target location;
measuring a temperature of the semiconductor chip at each predetermined location using a corresponding one of the plurality of thermal sensing elements; and
determining a temperature at the target location using the temperatures measured at each of the predetermined locations.

2. The method of claim 1, wherein the thermal sensing elements comprise thermal diodes or thermal ring oscillators.

3. The method of claim 1, wherein the target location comprises a hotspot.

4. The method of claim 1, wherein the target location comprises a processing unit.

5. The method of claim 1, wherein the temperature at the target location is determined from a temperature measured at a plurality of the predetermined locations.

6. The method of claim 1, wherein the temperature at the target location is determined from a temperature differential between at least one pair of predetermined location temperatures.

7. The method of claim 1, wherein the temperature at the target location is determined from a temperature measured at one of the predetermined locations and a temperature differential between at least one pair of predetermined location temperatures.

8. The method of claim 1, wherein the temperature at the target location is determined from a temperature measured at one of the predetermined locations and a weighted combination of temperature differentials between two or more pairs of predetermined location temperatures.

9. The method of claim 1, wherein the temperature at the target location is determined from temperatures measured at a plurality of the predetermined locations, and operational information for the semiconductor chip selected from the group consisting of a performance counter, an activity counter, a dynamic processor state, and configuration information.

10. The method of claim 1, wherein the temperature at the target location is determined from at least the maximum temperature measured at the predetermined locations.

11. The method of claim 1, wherein the temperature at the target location is determined from at least the temperature at the predetermined location located nearest to the target location.

12. The method of claim 1, further comprising altering operation of the semiconductor chip based on the temperature at the target location.

13. The method of claim 12, wherein altering operation of the semiconductor chip comprises one or more of decreasing voltage, decreasing clock frequency, and decreasing a number of instructions executed per cycle.

14. A method comprising:
forming a plurality of thermal sensing elements on a semiconductor chip;
measuring a temperature of the semiconductor chip corresponding to each respective thermal sensing element; and
determining a temperature at a target location on the semiconductor chip using two or more temperature measurements from the plurality of thermal sensing element.

15. The method of claim 14, wherein the thermal sensing elements comprise thermal diodes or thermal ring oscillators.

16. The method of claim 14, wherein the target location comprises a hotspot overlying a processing unit.

17. The method of claim 14, wherein the temperature at the target location is determined from one of the measured temperatures and a weighted combination of temperature differentials between two or more pairs of the measured temperatures.

18. The method of claim 14, wherein the temperature at the target location is determined from the maximum measured temperature.

19. The method of claim 14, further comprising altering operation of the semiconductor chip based on the temperature at the target location.

20. A system comprising:
a semiconductor chip having a target location; and
a plurality of thermal sensing elements located on the semiconductor chip proximate to the target location, wherein the target location comprises a hotspot.
